(19) United States
(12) Patent Application Publication
(10) Pub. No.: US 2024/0079420 A1
(43) Pub. Date: Mar. 7, 2024

(54) DISPLAY DEVICE AND METHOD OF MANUFACTURING THE SAME

(71) Applicant: Samsung Display Co., LTD., Yongin-si (KR)

(72) Inventors: KEUNWOO KIM, Yongin-si (KR); TAEWOOK KANG, Yongin-si (KR); DOO-NA KIM, Yongin-si (KR); HANBIT KIM, Yongin-si (KR); JIYEONG SHIN, Yongin-si (KR); JUN HYUNG LIM, Yongin-si (KR)

(21) Appl. No.: 18/226,986

(22) Filed: Jul. 27, 2023

(30) Foreign Application Priority Data
Sep. 5, 2022 (KR) 10-2022-0111985

(51) Int. Cl. H01L 27/12; G09G 3/3233; H01L 29/40; H01L 29/66; H01L 29/786

(52) U.S. Cl. CPC H01L 27/1296; G09G 3/3233; H01L 27/1222; H01L 27/1237; H01L 29/408; H01L 29/66757; H01L 29/78675; G09G 2300/0819; G09G 2300/0842

(57) ABSTRACT

A display device includes a transistor including an active layer including first and second active areas, where the first active area includes a first drain area, a source area, and a first channel area between the source area and the first drain area, and the second active area includes the source area, a second drain area, and a second channel area between the source area and the second drain area, a gate insulating layer on the active layer, first and second charge layers at an interface between the first channel area and the gate insulating layer and at an interface between the second channel area and the gate insulating layer, where the first charge layer is adjacent to the source area, and the second charge layer is adjacent to the first and second drain areas and has a charge opposite to a charge of a first charge layer.

This application claims priority to Korean Patent Application No. 10-2022-0111985, filed on Sep. 5, 2022, and all the benefits accruing therefrom under 35 U.S.C. § 119, the content of which in its entirety is herein incorporated by reference.

### BACKGROUND

### 1. Field

Embodiments of the invention relate to a display device and a method of manufacturing the display device.

### 2. Description of the Related Art

An aging process is a process for preventing a change in characteristics of a transistor of a display device even when a user uses the display device by applying stress to the transistor in advance in a manufacturing process of the display device.

### SUMMARY

During an aging process in a manufacturing process of a display device, if a threshold voltage of a transistor in the display device is shifted, performance of the transistor may be degraded, such that performance of the display device may deteriorate.

Embodiments provide a display device with improved display performance.

Embodiments provide a method for manufacturing a display device with improved display performance.

A display device according to an embodiment includes a substrate, a transistor disposed on the substrate, where the transistor includes an active layer including a first active area and a second active area, where the first active area includes a first drain area, a source area, and a first channel area located between the first drain area and the source area, and the second active area includes the source area, a second drain area, and a second channel area located between the source area and the second drain area, a gate insulating layer disposed on the active layer, a first charge layer defined at an interface between the first channel area and the gate insulating layer to be adjacent to the source area and at an interface between the second channel area and the gate insulating layer to be adjacent to the source area, and a second charge layer defined at the interface between the first channel area and the gate insulating layer to be adjacent to the first drain area and at the interface between the second channel area and the gate insulating layer to be adjacent to the second drain area, where the second charge layer has a charge opposite to a charge of the first charge layer.

In an embodiment, the second charge layer shifts a threshold voltage of the transistor in one of a positive direction and a negative direction, and the first charge layer may shift a threshold voltage of the transistor in the other of the positive direction and the negative direction.

In an embodiment, the first charge layer and the second charge layer may be spaced apart from each other.

In an embodiment, the transistor may include a first gate electrode overlapping the first channel area and a second gate electrode overlapping the second channel area, and the first gate electrode and the second gate electrode may be electrically connected to each other.

In an embodiment, the transistor may include a first sub-transistor defined by the first active area and the first gate electrode and a second sub-transistor defined by the second active area and the second gate electrode, and the first sub-transistor and the second sub-transistor may be connected to each other.

In an embodiment, each of the first charge layer and the second charge layer may overlap the first gate electrode and the second gate electrode when viewed in a thickness direction of the substrate.

In an embodiment, each of the first drain area, the source area, and the second drain area may be doped with P-type impurity ions.

In an embodiment, the first charge layer may have a positive charge, and the second charge layer may have a negative charge.

In an embodiment, each of the first drain area, the source area, and the second drain area may be doped with N-type impurity ions.

In an embodiment, the first charge layer may have a negative charge, and the second charge layer may have a positive charge.

In an embodiment, the active layer may include a silicon semiconductor.

A method of manufacturing a display device according to an embodiment includes forming an active layer including a first active area and a second active area on a substrate, where the first active area includes a first drain area, a source area, and a first channel area located between the first drain area and the source area, and the second active area includes the source area, a second drain area, and a second channel area located between the source area and the second drain area, forming a gate insulating layer on the active layer, forming a first charge layer at an interface between the first channel area and the gate insulating layer to be adjacent to the source area and at an interface between the second channel area and the gate insulating layer to be adjacent to the source area, and forming a second charge layer having a charge opposite to a charge of the first charge layer at the interface between the first channel area and the gate insulating layer to be adjacent to the first drain area and at the interface between the second channel area and the gate insulating layer to be adjacent to the second drain area.

In an embodiment, the forming the first charge layer may include selectively implanting ions to an area adjacent to the source area at the interface between the first channel area and the gate insulating layer and to an area adjacent to the source area at the interface between the second channel area and the gate insulating layer using a mask.

In an embodiment, the method further includes forming a first gate electrode overlapping the first channel area and a second gate electrode overlapping the second channel area on the gate insulating layer, and the forming the first charge layer may include applying a bias voltage to each of the first gate electrode and the second gate electrode.

In an embodiment, the forming the second charge layer may include selectively implanting ions to an area adjacent to the first drain area at the interface between the first channel area and the gate insulating layer and to an area adjacent to the second drain area at the interface between the second channel area and the gate insulating layer using a mask.

In an embodiment, the method further includes forming a first gate electrode overlapping the first channel area and a second gate electrode overlapping the second channel area on the gate insulating layer, and the forming the second charge layer may include applying a bias voltage to each of the first gate electrode and the second gate electrode.

In an embodiment, each of the first drain area, the source area, and the second drain area may be doped with P-type impurity ions, the first charge layer may have a positive charge, and the second charge layer may have a negative charge.

In an embodiment, each of the first drain area, the source area, and the second drain area may be doped with N-type impurity ions, the first charge layer may have a negative charge, and the second charge layer may have a positive charge.

In an embodiment, the first charge layer and the second charge layer may be spaced apart from each other.

In an embodiment, the active layer may include a silicon semiconductor.

The display device according to embodiments may include a transistor including an active layer including a first active area including a first drain area, a source area, and a first channel area and a second active area including a second drain area, the source area, and the second channel area and a gate insulating layer disposed on the active layer.

In such embodiments, the display device may further include a first charge layer and a second charge layer defined at an interface between the first channel area and the first gate insulating layer and at an interface between the second channel area and the first gate insulating layer. In such embodiments, the first charge layer and the second charge layer may have charges opposite to each other. In such embodiments, the first charge layer and the second charge layer may shift a threshold voltage of the transistor in opposite directions, such that a shift of the threshold voltage of the transistor by an aging process or the like may be effectively compensated. Accordingly, an occurrence of defects and yield reduction of pixels may be substantially minimized or effectively prevented, and a display performance of the display device may be improved.

### BRIEF DESCRIPTION OF THE DRAWINGS

Illustrative, non-limiting embodiments will be more clearly understood from the following detailed description taken in conjunction with the accompanying drawings.

FIG. 1 is a block diagram illustrating a display device according to an embodiment.

FIG. 2 is a circuit diagram illustrating a pixel disposed on the pixel part of FIG. 1.

FIG. 3 is a plan view illustrating a transistor included in the pixel of FIG. 2.

FIG. 4 is a cross-sectional view taken along line I-I′ of FIG. 3.

FIGS. 5 to 8 are cross-sectional views illustrating a manufacturing method of the display device of FIG. 1 according to an embodiment.

FIGS. 9 to 12 are cross-sectional views illustrating a manufacturing method of the display device of FIG. 1 according to an alternative embodiment.

FIGS. 13 to 15 are cross-sectional views illustrating a manufacturing method of the display device of FIG. 1 according to another alternative embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

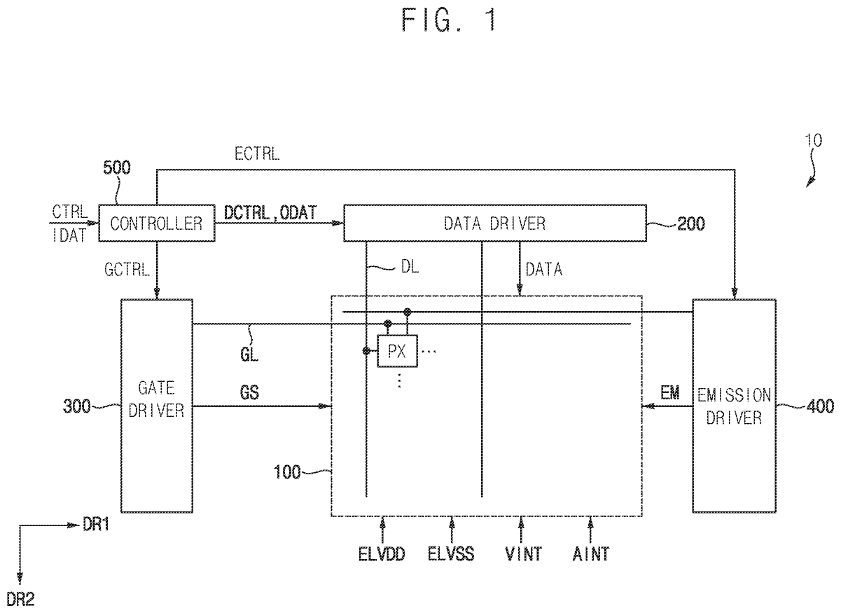

FIG. 1 is a block diagram illustrating a display device according to an embodiment.

Referring to FIG. 1, an embodiment of a display device 10 may include a pixel part 100, a data driving circuit (or a data driver) 200, a gate driving circuit (or a gate driver) 300, a light emitting driving circuit (or an emission driver) 400, and a controller 500.

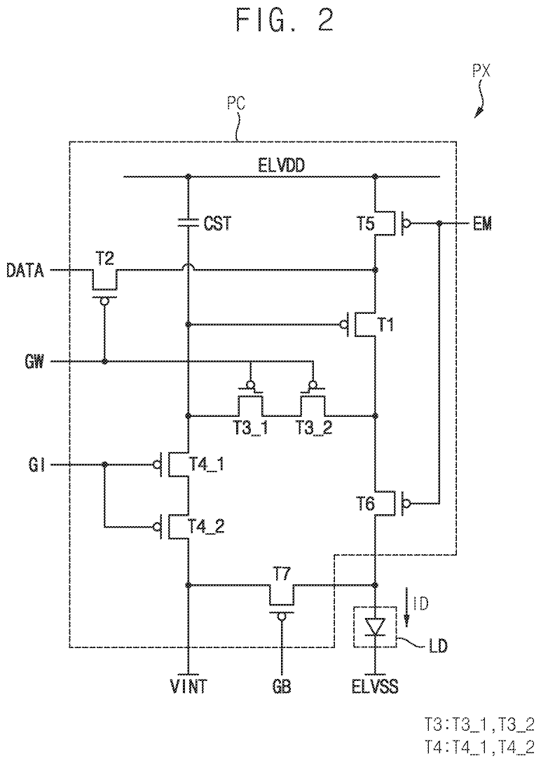

The pixel part 100 may include the plurality of pixels PX. Each of the pixels PX may emit light having a preset color. The pixel part 100 may have an RGBG pixel structure, and each of the pixels PX may emit red, green, or blue light. Each of the pixels PX may include a pixel circuit (e.g., the pixel circuit PC of FIG. 2) and a light emitting device (e.g., the light emitting device LD of FIG. 2). Each of the pixels PX may be driven through the pixel circuit.

In an embodiment, the data driving circuit 200 may be implemented with one or more integrated circuits (IC). In an alternative embodiment, the data driving circuit 200 may be mounted on the pixel part 100 or may be integrated in a peripheral part of the pixel part 100.

The data driving circuit 200 may generate a data voltage DATA based on an output image data ODAT and a data control signal DCTRL. In an embodiment, for example, the data driving circuit 200 may generate the data voltage DATA corresponding to the output image data ODAT and output the data voltage DATA in response to the data control signal DCTRL. The data driving circuit 200 may output the data voltage DATA through a data line DL. In an embodiment, for example, the data driving circuit 200 may output the data voltage DATA to the pixels PX through the data line DL.

The output image data ODAT may be RGB data for an image displayed in the pixel part 100, and the data control signal DCTRL may include an output data enable signal, a horizontal start signal, and a load signal.

The gate driving circuit 300 may generate a gate signal GS based on a gate control signal GCTRL. The gate signal GS may be a clock signal. The gate signal GS may have a turn-on voltage for turning on a transistor and a turn-off voltage for turning off the transistor. The gate driving circuit 300 may sequentially output the gate signal GS through a gate line GL. In an embodiment, for example, the gate driving circuit 300 may output the gate signal GS to the pixels PX through the gate line GL. The gate control signal GCTRL may include a vertical start signal and a clock signal. In an embodiment, the gate driving circuit 300 may be mounted on the pixel part 100 or may be integrated in the peripheral part of the pixel part 100. In an alternative embodiment, the gate driving circuit 300 may be implemented as one or more ICs.

The light emitting driving circuit 400 may generate a light emitting driving signal EM based on a light emitting control signal ECTRL. The light emitting driving signal EM may be a clock signal and may have a turn-on voltage and a turn-off voltage. The light emitting driving circuit 400 may sequentially output the light emitting driving signal EM. The emission control signal ECTRL may include a vertical start signal and a clock signal. In an embodiment, the light emitting driving circuit 400 may be mounted on the pixel part 100 or may be integrated in the peripheral part of the pixel part 100. In an alternative embodiment, the light emitting driving circuit 400 may be implemented as one or more ICs.

The controller 500 (e.g., a timing controller) may receive an input image data IDAT and a control signal CTRL from an external host processor (e.g., a graphics processing unit (GPU)). In an embodiment, for example, the input image data IDAT may be RGB data including red image data, green image data, and blue image data. The controller 500 may generate the gate control signal GCTRL, the data control signal DCTRL, and the output image data ODAT based on the input image data IDAT and the control signal CTRL.

A first voltage ELVDD may be applied to the pixel part 100. The first voltage ELVDD may be applied to the pixel part 100 through a power line. A second voltage ELVSS (e.g., a low power supply voltage) may be applied to the pixel part 100. The second voltage ELVSS may be applied to the pixel part 100 through a common electrode. A transistor initialization voltage VINT and an anode initialization voltage AINT may be applied to the pixel part 100.

FIG. 2 is a circuit diagram illustrating a pixel disposed on the pixel part of FIG. 1. In an embodiment, for example, each of the pixels PX may include a light emitting device LD and a pixel circuit PC for driving the light emitting device LD.

Referring to FIG. 2, an embodiment of the pixel circuit PC may include first to seventh transistors T1, T2, T3, T4, T5, T6, and T7, and a storage capacitor CST.

The first transistor T1 may include a first gate terminal, a first source terminal, and a first drain terminal. The first source terminal of the first transistor T1 may receive the data voltage DATA. The first drain terminal of the first transistor T1 may be electrically connected to the light emitting device LD through the sixth transistor T6. The first transistor T1 may generate a driving current ID. The first transistor T1 may transfer the driving current ID to the light emitting device LD.

The second transistor T2 may be turned on or off in response to a first gate signal GW. In an embodiment, for example, where the second transistor T2 is a P-channel transistor, e.g., a P-channel metal-oxide-semiconductor (PMOS) transistor, the second transistor T2 may be turned off when the first gate signal GW has a positive voltage level, and the first gate signal GW may be turned on when the first gate signal GW has a negative voltage level.

In an embodiment, the third transistor T3 may have a dual transistor structure. In an embodiment, for example, the third transistor T3 may include a first sub-transistor T3_1 and a second sub-transistor T3_2. The first sub-transistor T3_1 and the second sub-transistor T3_2 may be connected to each other.

The first sub-transistor T3_1 and the second sub-transistor T3_2 of the third transistor T3 may receive the first gate signal GW. In such an embodiment where the third transistor T3 has a dual transistor structure, a reliability of the third transistor T3 may be improved.

The third transistor T3 may be turned on or off in response to the first gate signal GW. In an embodiment, for example, where the third transistor T3 is a P-channel transistor or a PMOS transistor, the third transistor T3 may be turned off when the first gate signal GW has a positive voltage level, and the first gate signal GW may be turned on when the first gate signal GW has a negative voltage level. During a period in which the third transistor T3 is turned on in response to the first gate signal GW, the third transistor T3 may diode-connect the first transistor T1. Accordingly, the third transistor T3 may compensate for a threshold voltage of the first transistor T1.

In an embodiment, the fourth transistor T4 may have a dual transistor structure. In an embodiment, for example, the fourth transistor T4 may include a third sub-transistor T4_1 and a fourth sub-transistor T4_2. The third sub-transistor T4_1 and the fourth sub-transistor T4_2 may be connected to each other.

The fourth transistor T4 may be connected to the third transistor T3 and the first gate terminal of the first transistor T1. The third sub-transistor T4_1 may be connected to the storage capacitor CST and the first sub-transistor T3_1 of the third transistor T3. The fourth sub-transistor T4_2 may receive the transistor initialization voltage VINT.

The third sub-transistor T4_1 and the fourth sub-transistor T4_2 of the fourth transistor T4 may receive a second gate signal GI. Herein, the second gate signal GI may be referred to as an initialization gate signal. In such an embodiment, where the fourth transistor T4 has a dual transistor structure, a reliability of the fourth transistor T4 may be improved. The fourth transistor T4 may connect the first gate terminal of the first transistor T1 and the transistor initialization voltage VINT.

The fourth transistor T4 may be turned on or off in response to the second gate signal GI. In an embodiment, for example, where the fourth transistor T4 is a P-channel transistor or a PMOS transistor, the fourth transistor T4 may be turned off when the second gate signal GI has a positive voltage level, and may be turned on when the second gate signal GI has a negative voltage level.

During a period in which the fourth transistor T4 is turned on in response to the second gate signal GI, the first gate terminal of the first transistor T1 may be electrically connected to the transistor initialization voltage VINT. Accordingly, the fourth transistor T4 may transmit the transistor initialization voltage VINT to the first gate terminal of the first transistor T1 in response to the second gate signal GI.

The fifth transistor T5 may receive the light emitting driving signal EM. The fifth transistor T5 may receive the first voltage ELVDD. The fifth transistor T5 may be connected to the first source terminal of the first transistor T1. When the fifth transistor T5 is turned on in response to the light emitting driving signal EM, the fifth transistor T5 may provide the first voltage ELVDD to the first transistor T1.

The sixth transistor T6 may receive the light emitting driving signal EM. The sixth transistor T6 may be connected to the first drain terminal of the first transistor T1. The sixth transistor T6 may be connected to the light emitting device LD. When the sixth transistor T6 is turned on in response to the light emitting driving signal EM, the sixth transistor T6 may provide the driving current ID to the light emitting device LD. Herein, each of the fifth transistor T5 and the sixth transistor T6 may be referred to as a light emitting control transistor.

The seventh transistor T7 may receive a third gate signal GB. For example, the third gate signal GB may be referred to as a bypass gate signal. The seventh transistor T7 may be connected to the light emitting device LD. The seventh transistor T7 may receive the anode initialization voltage AINT. When the seventh transistor T7 is turned on in response to the third gate signal GB, the seventh transistor T7 may provide the anode initialization voltage AINT to the light emitting device LD. Accordingly, the seventh transistor T7 may initialize the light emitting device LD with the anode initialization voltage AINT. Herein, the seventh transistor T7 may be referred to as an anode initialization transistor.

The storage capacitor CST may include a first terminal and a second terminal. The first terminal of the storage capacitor CST may be connected to the first transistor T1, and the second terminal of the storage capacitor CST may receive the first voltage ELVDD. The storage capacitor CST may maintain a voltage level of the first gate terminal of the first transistor T1 during an inactive period of the first gate signal GW.

The light emitting device LD may include a first terminal (e.g., anode terminal) and a second terminal (e.g., cathode terminal). The first terminal of the light emitting device LD may be connected to the sixth transistor T6 to receive the driving current ID, and the second terminal may receive the second voltage ELVSS. The light emitting device LD may generate light having luminance corresponding to the driving current ID.

FIG. 2 shows the connection structure of the pixel circuit PC and the light emitting device LD according to an embodiment, and the connection structure of the pixel circuit PC and the light emitting device LD may be variously changed or modified.

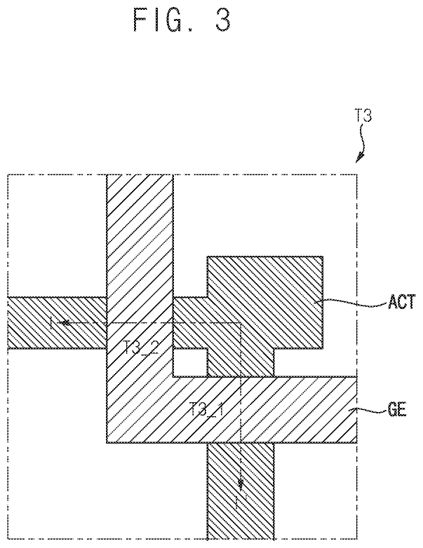

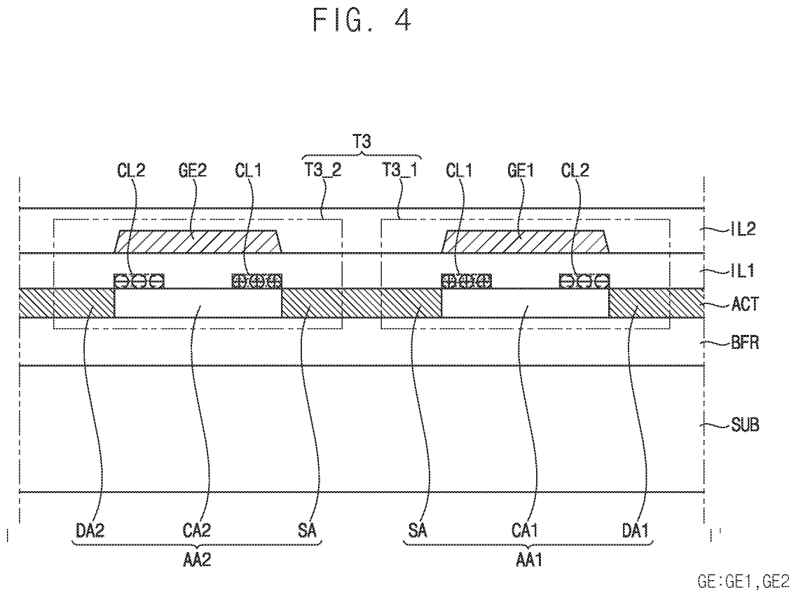

FIG. 3 is a plan view illustrating a transistor included in the pixel of FIG. 2. FIG. 4 is a cross-sectional view taken along line I-I′ of FIG. 3. For example, the transistor of FIGS. 3 and 4 may correspond to the third transistor T3 of FIG. 2.

Referring to FIGS. 3 and 4, each of the pixels PX may include a substrate SUB, a buffer layer BFR, a first gate insulating layer ILL a first charge layer CL1, a second charge layer CL2, the third transistor T3, and a second gate insulating layer IL2. The third transistor T3 may include an active layer ACT and a gate electrode GE.

The substrate SUB may include glass, plastic, or the like. In an embodiment, the substrate SUB may include a flexible material, and thus, the substrate SUB may have a flexible property. In an embodiment, the substrate SUB may have a multi-layered structure in which a first polyimide layer, a first barrier layer, a second polyimide layer, and a second barrier layer are sequentially stacked one on another.

The buffer layer BFR may be disposed on the substrate SUB. The buffer layer BFR may prevent diffusion of metal atoms or impurities from the substrate SUB into the transistor (e.g., the third transistor T3). In an embodiment, the buffer layer BFR may include an inorganic insulating material. In such an embodiment, the inorganic insulating material of the buffer layer BFR may include at least one selected from silicon oxide, silicon nitride, and silicon oxynitride. These may be used alone or in combination with each other. In addition, the buffer layer BFR may be formed of (or defined by) a single layer or multiple layers, that is, may have a single-layer structure or a multi-layer structure.

The active layer ACT may be disposed on the buffer layer BFR. The active layer ACT may include an oxide semiconductor, an inorganic semiconductor, or an organic semiconductor. In an embodiment, the active layer ACT may include a silicon semiconductor. In an embodiment, for example, the active layer ACT may include polysilicon.

The active layer ACT may include a first active area AA1 and a second active area AA2. The first active area AA1 may include a first drain area DA1, a source area SA, and a first channel area CA1 located between the first drain area DA1 and the source area SA. The second active area AA2 may include a second drain area DA2, the source area SA, and a second channel area CA2 located between the second drain area DA2 and the source area SA. In such an embodiment, the first active area AA1 and the second active area AA2 may share the source area SA.

In an embodiment, the first active area AA1 may function as a semiconductor pattern of the first sub-transistor T3_1 of the third transistor T3. The second active area AA2 may function as a semiconductor pattern of the second sub-transistor T3_2 of the third transistor T3.

In an embodiment, each of the first drain area DA1, the source area SA, and the second drain area DA2 may be doped with P-type impurity ions. In an alternative embodiment, each of the first drain area DA1, the source area SA, and the second drain area DA2 may be doped with N-type impurity ions.

The first gate insulating layer IL1 may be disposed on the active layer ACT. In an embodiment, the first gate insulating layer IL1 may cover (or be disposed over) the active layer ACT. In an embodiment, the first gate insulating layer IL1 may include an inorganic insulating material. In such an embodiment, the inorganic insulating material of the first gate insulating layer IL1 may include at least one selected from silicon oxide, silicon nitride, and silicon oxynitride. These may be used alone or in combination with each other. In an embodiment, for example, the first gate insulating layer IL1 may include silicon oxide.

The gate electrode GE may be disposed on the first gate insulating layer ILL In an embodiment, the gate electrode GE may include a metal, an alloy, a metal nitride, a conductive metal oxide, a transparent conductive material, or the like.

In an embodiment, when the third transistor T3 has a dual transistor structure, the third transistor T3 may include the gate electrode GE of a dual structure. In an embodiment, for example, the gate electrode GE may include a first gate electrode GE1 overlapping the first active area AA1 and a second gate electrode GE2 overlapping the second active area AA2. In such an embodiment, the first gate electrode GE1 may overlap the first channel area CA1 of the first active area AA1, and the second gate electrode GE2 may overlap the second channel area CA2 of the second active area AA1. The first gate electrode GE1 and the second gate electrode GE2 may be electrically connected to each other.

The first active area AA1 and the first gate electrode GE1 may form (or collectively define) the first sub-transistor T3_1 of the third transistor T3, and the second active area AA2 and the second gate electrode GE2 may form the second sub-transistor T3_2 of the third transistor T3. A same signal may be applied to the first gate electrode GE1 and the second gate electrode GE2. In an embodiment, for example, the first gate signal GW shown in FIG. 2 may be applied to the first gate electrode GE1 and the second gate electrode GE2.

The second gate insulating layer IL2 may be disposed on the first gate insulating layer IL1 on which the gate electrode GE is disposed. The second gate insulating layer IL2 may cover the gate electrode GE. In an embodiment, the second gate insulating layer IL2 may include an inorganic insulating material. In such an embodiment the inorganic insulating material of the second gate insulating layer IL2 may include at least one selected from silicon oxide, silicon nitride, and silicon oxynitride. These may be used alone or in combination with each other. In an embodiment, for example, the second gate insulating layer IL2 may include silicon nitride.

The first charge layer CL1 and the second charge layer CL2 may be defined at an interface between the active layer ACT and the first gate insulating layer ILL In an embodiment, for example, the first charge layer CL1 and the second charge layer CL2 may be defined at an interface between the first channel area CA1 and the first gate insulating layer IL1 and an interface between the second channel area CA2 and the first gate insulating layer ILL

In an embodiment, the first charge layer CL1 may be defined in an area adjacent to the source area SA (or to be adjacent to the source area SA) at the interface between the first channel area CA1 and the gate insulating layer IL1 and defined in an area adjacent to the source area SA (or to be adjacent to the source area SA) at the interface between the second channel area CA2 and the gate insulating layer ILL The second charge layer CL2 may be defined in an area adjacent to the first drain area DA1 at the interface between the first channel area CA1 and the gate insulating layer IL1 and an area adjacent to the second drain area DA2 at the interface between the second channel area CA2 and the gate insulating layer IL1.

In an embodiment, the first charge layer CL1 and the second charge layer CL2 may be spaced apart from each other. On a plane or when viewed in a thickness direction of the substrate SUB, the first charge layer CL1 and the second charge layer CL2 may overlap the gate electrode GE. In such an embodiment, the first charge layer CL1 and the second charge layer CL2 defined at the interface between the first channel area CA1 and the first gate insulating layer IL1 may overlap the first gate electrode GE1. In addition, the first charge layer CL1 and the second charge layer CL2 defined at the interface between the second channel area CA2 and the second gate insulating layer IL2 may overlap the second gate electrode GE2.

Accordingly, the first charge layer CL1 and the second charge layer CL2 are defined corresponding to each of the first sub-transistor T3_1 and the second sub-transistor T3_2 of the third transistor T3.

A charge of the first charge layer CL1 and a charge of the second charge layer CL2 may be opposite to each other. In an embodiment, for example, as shown in FIG. 4, where each of the first drain area DA1, the source area SA, and the second drain area DA2 is doped with P-type impurity ions, the first charge layer CL1 may have a positive charge, and the second charge layer CL2 may have a negative charge. In an alternative embodiment, although not shown, where each of the first drain area DA1, the source area SA, and the second drain area DA2 is doped with N-type impurity ions, the first charge layer CL1 may have a positive charge, and the second charge layer CL2 may have a negative charge.

In an embodiment where the first charge layer CL1 and the second charge layer CL2 have a positive charge, each of the first charge layer CL1 and the second charge layer CL2 may be defined as an area where holes are trapped in the lattice of the first gate insulating layer IL1. In an embodiment, where the first charge layer CL1 and the second charge layer CL2 have a negative charge, each of the first charge layer CL1 and the second charge layer CL2 may be defined as an area where electrons are trapped in the lattice of the first gate insulating layer IL1.

In an embodiment, a direction in which the first charge layer CL1 shifts the threshold voltage of the third transistor T3 and a direction in which the second charge layer CL2 shifts the threshold voltage of the third transistor T3 may be opposite to each other. In an embodiment, for example, a direction in which the first charge layer CL1 shifts the threshold voltage of the first sub-transistor T3_1 and a direction in which the second charge layer CL2 shifts the threshold voltage of the first sub-transistor T3_1 may be opposite to each other. Also, a direction in which the first charge layer CL1 shifts the threshold voltage of the second sub-transistor T3_2 and a direction in which the second charge layer CL2 shifts the threshold voltage of the second sub-transistor T3_2 may be opposite to each other.

In an embodiment, as shown in FIG. 4, where each of the first drain area DA1, the source area SA, and the second drain are DA2 is doped with P-type impurity ions, the first charge layer CL1 has a positive charge, and the second charge layer CL2 has a negative charge, the threshold voltage of the third transistor T3 may be shifted in a positive direction by the second charge layer CL2 and may be shifted in a negative direction by the first charge layer CL1.

In an alternative embodiment, although not shown, where each of the first drain area DA1, the source area SA, and the second drain are DA2 is doped with N-type impurity ions, the first charge layer CL1 has a negative charge, and the second charge layer CL2 has a positive charge, the threshold voltage of the third transistor T3 may be shifted in a negative direction by the second charge layer CL2 and may be shifted in a positive direction by the first charge layer CL1.

In such embodiments, as the first charge layer CL1 and the second charge layer CL2 shift the threshold voltage of the third transistor T3 in opposite directions, the shift of the threshold voltage of the third transistor T3 by an aging process or the like may be effectively compensated. Accordingly, an occurrence of defects and yield reduction of the pixels PX may be substantially minimized or effectively prevented, such that a display performance of the display device 10 may be improved.

Although FIGS. 3 and 4 show the structure of the third transistor T3 of FIG. 2 for convenience of illustration and description, the cross-sectional structure of the fourth transistor T4 of FIG. 2 may also be substantially the same as the cross-sectional structure of the transistor T3 shown in FIG. 4.

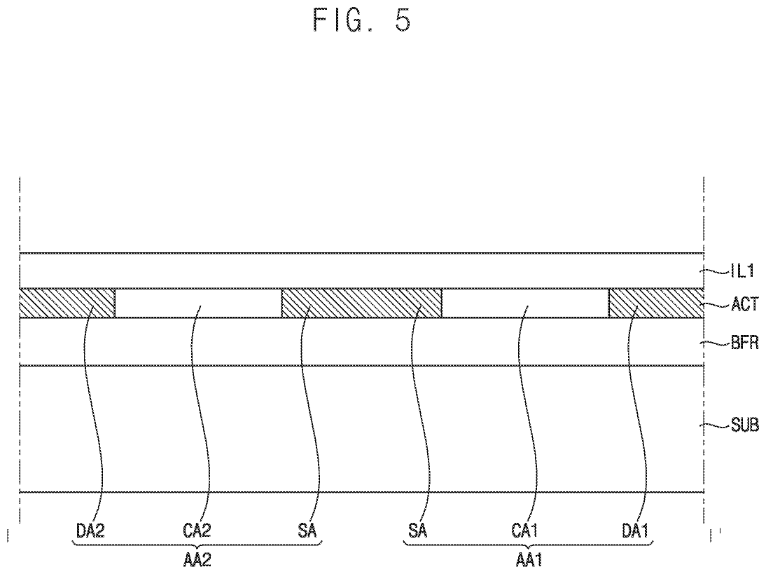

FIGS. 5 to 8 are cross-sectional views illustrating a manufacturing method of the display device of FIG. 1 according to an embodiment. Particularly, FIGS. 5 to 8 may be cross-sectional views illustrating an embodiment of a process of forming the third transistor T3 of FIGS. 3 and 4 among manufacturing processes of the display device 10.

Referring to FIG. 5, in an embodiment of a manufacturing method of the display device, the substrate SUB including a transparent or opaque material may be provided or prepared. The buffer layer BFR may be formed (or provided) on the substrate SUB. In an embodiment, the buffer layer BFR may include an inorganic material. The active layer ACT may be formed on the buffer layer BFR. In an embodiment, the active layer ACT may include a silicon semiconductor. In an embodiment, for example, after forming an amorphous silicon layer on the buffer layer BFR, the amorphous silicon layer may be crystallized to form a polycrystalline silicon layer.

The active layer ACT may include the first active area AA1 and the second active area AA2. The first active area AA1 may include the first drain area DA1, the source area SA, and the first channel area CA1 located between the first drain area DA1 and the source area SA. The second active area AA2 may include the second drain area DA2, the source area SA, and the second channel area CA2 located between the second drain area DA2 and the source area SA.

The first gate insulating layer IL1 may be formed on the active layer ACT. In an embodiment, the first gate insulating layer IL1 may have a single-layer structure including silicon oxide.

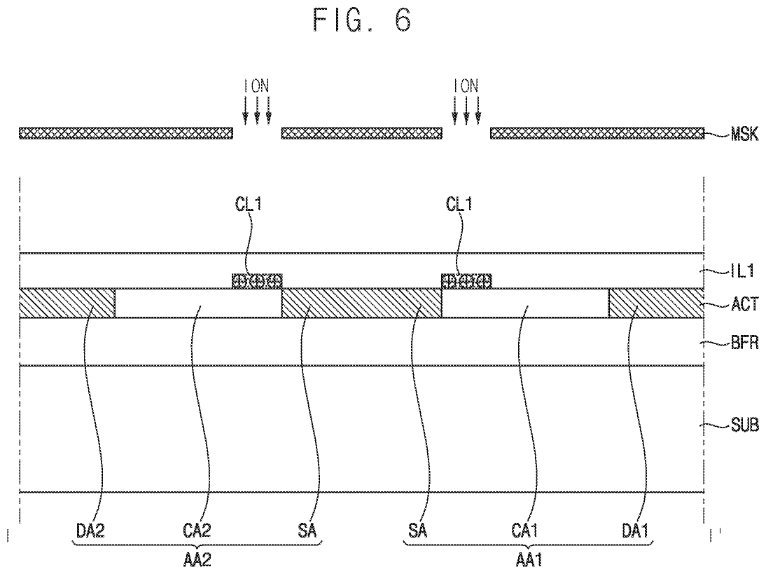

Referring to FIG. 6, the first charge layer CL1 may be formed in the area adjacent to the source area SA at the interface between the first channel area CA1 and the gate insulating layer IL1 and the area adjacent to the source area SA at the interface between the second channel area CA2 and the gate insulating layer IL1.

In an embodiment, as shown in FIG. 6, when each of the first drain area DA1, the source area SA, and the second drain area DA2 is doped with P-type impurity ions, the first charge layer CL1 may be formed to have a positive charge. In an alternative embodiment, although not shown, when each of the first drain area DA1, the source area SA, and the second drain area DA2 is doped with N-type impurity ions, the first charge layer CL1 may be formed to have a negative charge.

In an embodiment, the first charge layer CL1 may be formed by an ion implantation process. In an embodiment, for example, an ion implantation process for forming the first charge layer CL1 may be performed using a mask MSK positioned on the first gate insulating layer ILL In an embodiment, for example, the first charge layer CL1 may be formed by selectively implanting ions ION to the area adjacent to the source area SA at the interface between the first channel area CA1 and the gate insulating layer IL1 and the area adjacent to the source area SA at the interface between the second channel area CA2 and the gate insulating layer IL1 using the mask MSK.

In an embodiment, as shown in FIG. 6, when the ions ION are cation, the first charge layer CL1 may be formed to have a positive charge. In an alternative embodiment, although not shown, when the ions ION are anion, the first charge layer CL1 may be formed to have a negative charge.

In an embodiment, the mask MSK may be a hard mask. However, the invention is not limited thereto, and in an alternative embodiment, a photoresist pattern or a metal pattern remaining on the first gate insulating layer IL1 may function as the mask MSK.

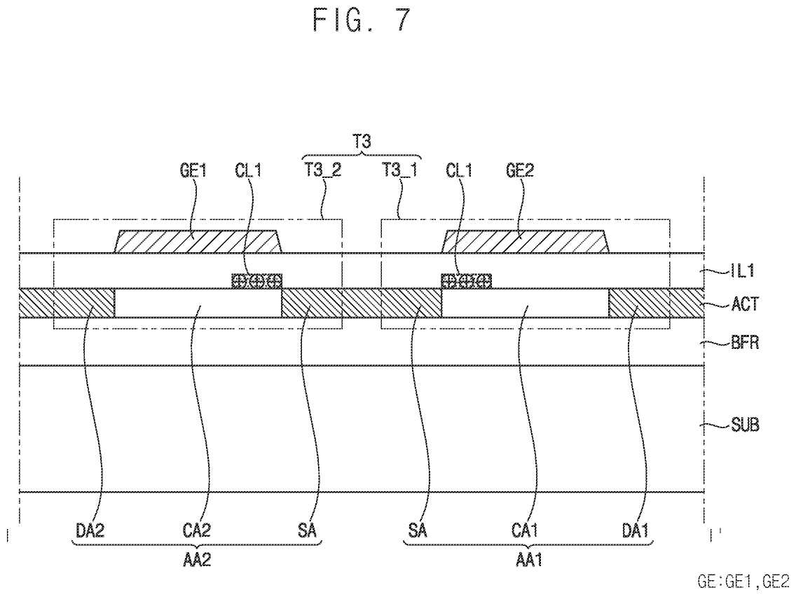

Referring to FIG. 7, a gate electrode GE may be formed on the first gate insulating layer ILL The gate electrode GE may include the first gate electrode GE1 overlapping the first active area AA1 and the second gate electrode GE2 overlapping the second active area AA2. In an embodiment, the first gate electrode GE1 may overlap the first channel area CA1 of the first active area AA1, and the second gate electrode GE2 may overlap the second channel area CA2 of the second active area AA2.

Accordingly, in such an embodiment, the first sub-transistor T3_1 defined by the first active area AA1 and the first gate electrode GE1 may be formed, and the second sub-transistor T3_2 defined by the second active area AA2 and the second gate electrode GE2 may be formed. Accordingly, the third transistor T3 including the first sub-transistor T3_1 and the second sub-transistor T3_2 may be formed. In such an embodiment, the third transistor T3 may have a dual transistor structure. The first sub-transistor T3_1 and the second sub-transistor T3_2 may be connected to each other.

In an embodiment, each of the first gate electrode GE1 and the second gate electrode GE2 may overlap the first charge layer CL1. Accordingly, the first charge layer CL1 may be defined to correspond to each of the first sub-transistor T3_1 and the second sub-transistor T3_2 of the third transistor T3.

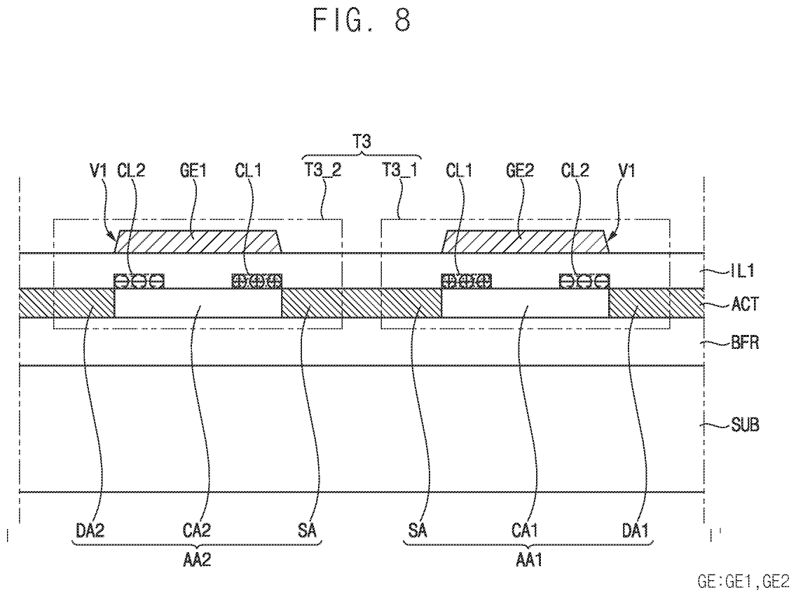

Referring to FIG. 8, the second charge layer CL2 may be formed in the area adjacent to the first drain area DA1 at the interface between the first channel area CA1 and the gate insulating layer IL1 and the area adjacent to the second drain area DA2 at the interface between the second channel area CA2 and the gate insulating layer IL1.

The second charge layer CL2 may have a charge opposite to a charge of the first charge layer CL1. In an embodiment, for example, as shown in FIG. 8, when the first charge layer CL1 has a positive charge, the second charge layer CL2 may have a negative charge. In an alternative embodiment, although not shown, when the first charge layer CL1 has a negative charge, the second charge layer CL2 may have a positive charge. In an embodiment, the second charge layer CL2 may be formed to be spaced apart from the first charge layer CL1.

In an embodiment, the second charge layer CL2 may be formed to overlap each of the first gate electrode GE1 and the second gate electrode GE2. Accordingly, the second charge layer CL2 may be defined to correspond to each of the first sub-transistor T3_1 and the second sub-transistor T3_2 of the third transistor T3.

In an embodiment, the second charge layer CL2 may be formed by applying a first bias voltage V1 to the gate electrode GE.

In an embodiment, for example, as shown in FIG. 8, as applying a bias voltage higher than that of the first drain area DA1 and the second drain area DA2 to the gate electrode GE, the second charge layer CL2 having a negative charge may be formed in the area adjacent to the first drain area DA1 at the interface between the first channel area CA1 and the gate insulating layer IL1 and the area adjacent to the second drain area DA2 at the interface between the second channel area CA2 and the gate insulating layer IL1.

In an alternative embodiment, although not shown, as applying a bias voltage lower than that of the first drain area DA1 and the second drain area DA2 to the gate electrode GE, the second charge layer CL2 having a positive charge may be formed in the area adjacent to the first drain area DA1 at the interface between the first channel area CA1 and the gate insulating layer IL1 and the area adjacent to the second drain area DA2 at the interface between the second channel area CA2 and the gate insulating layer IL1.

In an embodiment, as described above, the first charge layer CL1 and the second charge layer CL2 may shift the threshold voltage of the third transistor T3 in opposite directions. Accordingly, the shift of the threshold voltage of the third transistor T3 by an aging process or the like may be effectively compensated, such that an occurrence of defects and yield reduction of the pixels PX may be substantially minimized or effectively prevented, and a display performance of the display device 10 may be improved.

Thereafter, as shown in FIG. 4, the second gate insulating layer IL2 may be formed on the first gate insulating layer IL1 to cover the gate electrode GE. In an embodiment, the second gate insulating layer IL2 may have a single-layer structure including silicon nitride.

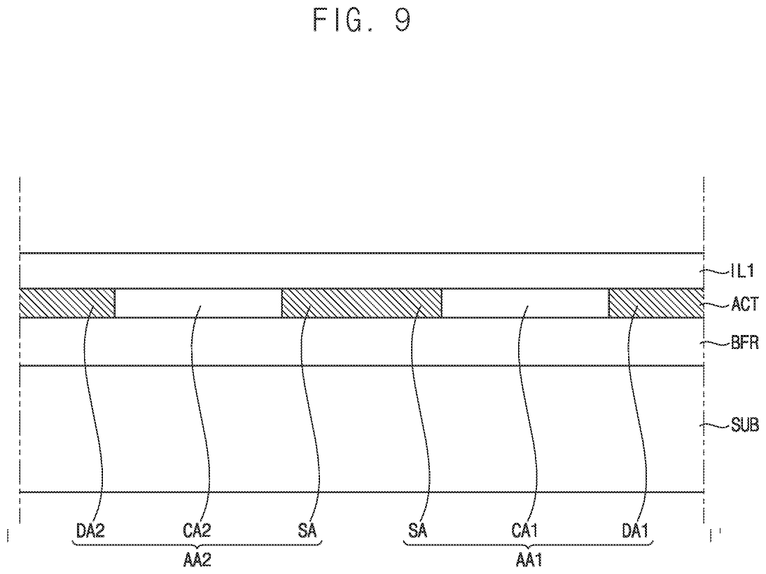

FIGS. 9 to 12 are cross-sectional views illustrating a manufacturing method of the display device of FIG. 1 according to an alternative embodiment. Particularly, FIGS. 9 to 12 may be cross-sectional views illustrating an alternative embodiment of a process of forming the third transistor T3 of FIGS. 3 and 4 among manufacturing processes of the display device 10.

Referring to FIGS. 9 to 12, an alternative embodiment of the manufacturing method of the display device 10 may be substantially same as the embodiment of the manufacturing method of the display device 10 described with reference FIGS. 5 to 8, except for a process of forming the second charge layer CL2. Therefore, any repetitive detailed descriptions of the same or like elements as those described above will be omitted or simplified.

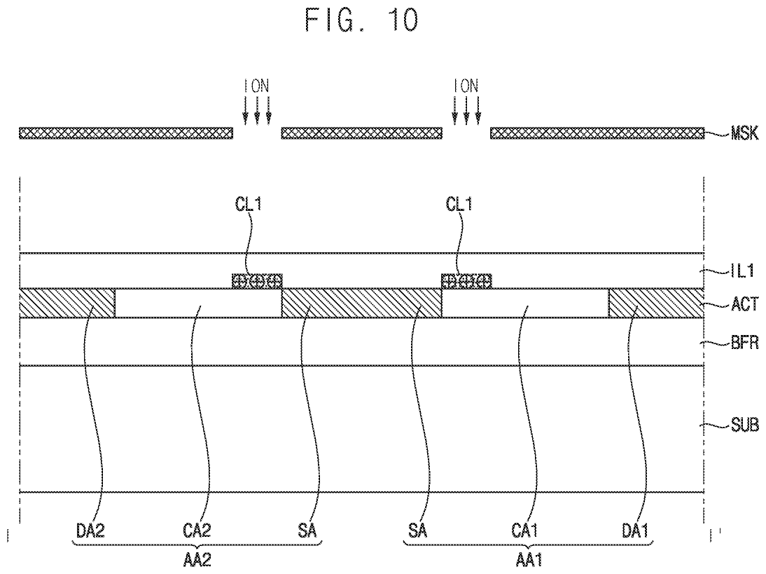

Referring to FIGS. 9 and 10, in an embodiment of the manufacturing method of the display device 10, the buffer layer BFR may be formed on the substrate SUB. The active layer ACT may be formed on the buffer layer BFR. The first gate insulating layer IL1 may be formed on the active layer ACT. Thereafter, by using an ion implantation process, the first charge layer CL1 may be formed at an interface between the active layer ACT and the first gate insulating layer IL1 in the area adjacent to the source area SA at the interface between the first channel area CA1 and the gate insulating layer IL1 and the area adjacent to the source area SA at the interface between the second channel area CA2 and the gate insulating layer IL1.

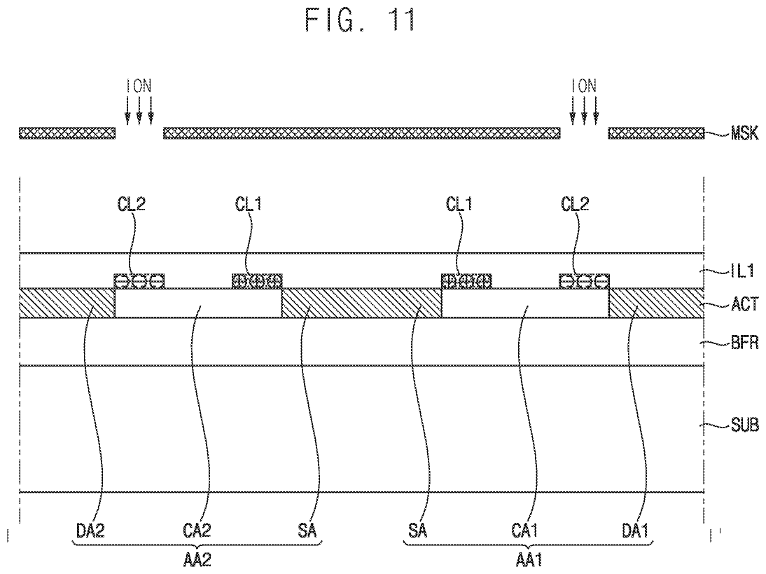

Referring to FIG. 11, the second charge layer CL2 may be formed by an ion implantation process. In an embodiment, for example, an ion implantation process for forming the second charge layer CL2 may be performed using a mask MSK positioned on the first gate insulating layer ILL In an embodiment, for example, the second charge layer CL1 may be formed by selectively implanting ions ION to the area adjacent to the first drain area DA1 at the interface between the first channel area CA1 and the gate insulating layer IL1 and the area adjacent to the second drain area DA2 at the interface between the second channel area CA2 and the gate insulating layer IL1 using the mask MSK.

In an embodiment, as shown in FIG. 11, when the ions ION are anion, the second charge layer CL2 may be formed to have a negative charge. In an alternative embodiment, although not shown, when the ions ION are cation, the first charge layer CL1 may be formed to have a positive charge.

In an embodiment, the mask MSK may be a hard mask. However, the invention is not limited thereto, and in an alternative embodiment, a photoresist pattern or a metal pattern remaining on the first gate insulating layer IL1 may function as the mask MSK.

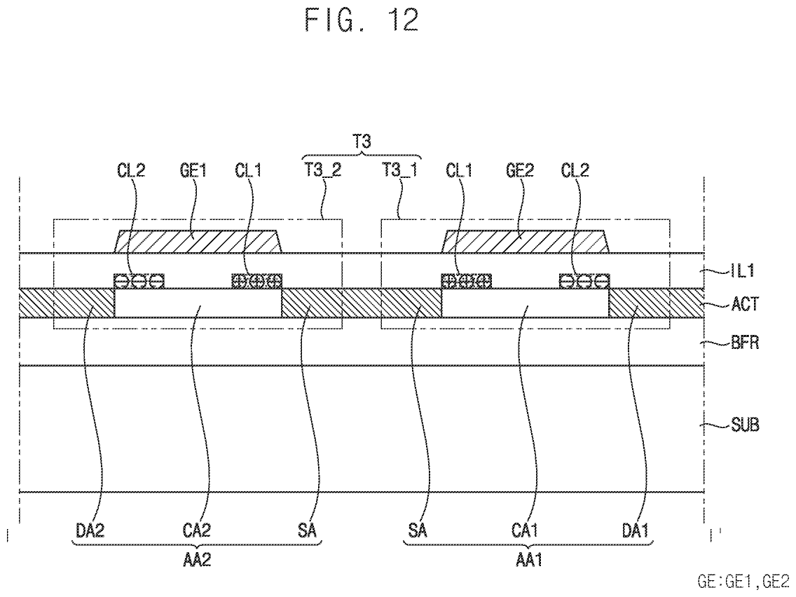

Thereafter, referring to FIG. 12, the gate electrode GE may be formed on the first gate insulating layer IL1.

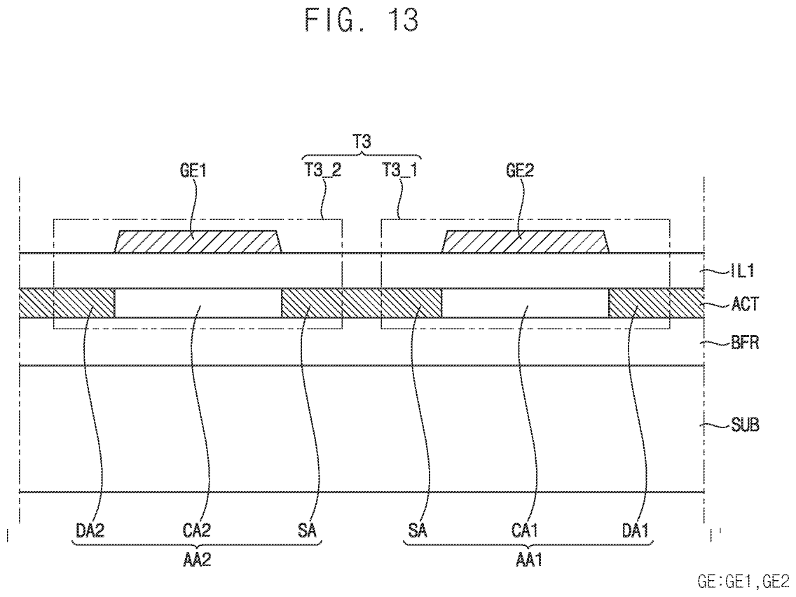

FIGS. 13 to 15 are cross-sectional views illustrating a manufacturing method of the display device of FIG. 1 according to another alternative embodiment. Particularly, FIGS. 13 to 15 may be cross-sectional views illustrating another alternative embodiment of a process of forming the third transistor T3 of FIGS. 3 and 4 among manufacturing processes of the display device 10.

Referring to FIGS. 13 to 15, another alternative embodiment of the manufacturing method of the display device 10 may be substantially same as the embodiment of the manufacturing method of the display device 10 described with reference FIGS. 5 to 8, except for the process of forming the first charge layer CL1. Therefore, any repetitive detailed descriptions of the same or like elements as those described above will be omitted or simplified.

Referring to FIG. 13, in an embodiment of the manufacturing method of the display device 10, the buffer layer BFR may be formed on the substrate SUB. The active layer ACT may be formed on the buffer layer BFR. The first gate insulating layer IL1 may be formed on the active layer ACT. Thereafter, the gate electrode GE may be formed on the first gate insulating layer IL1.

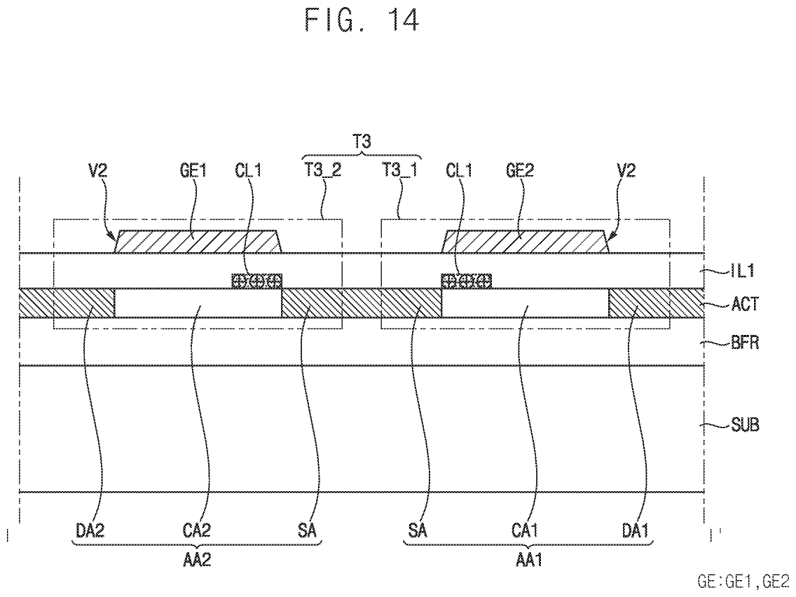

Referring to FIG. 14, in an embodiment, the first charge layer CL1 may be formed by applying a second bias voltage V2 to the gate electrode GE.

In an embodiment, for example, as shown in FIG. 14, as applying a bias voltage lower than that of the source area SA to the gate electrode GE, the first charge layer CL1 having a positive charge may be formed in the area adjacent to the source area SA at the interface between the first channel area CA1 and the gate insulating layer IL1 and the area adjacent to the source area SA at the interface between the second channel area CA2 and the gate insulating layer IL1.

In an alternative embodiment, although not shown, as applying a bias voltage higher than that of the source area SA to the gate electrode GE, the first charge layer CL1 having a negative charge may be formed in the area adjacent to the source area SA at the interface between the first channel area CA1 and the gate insulating layer IL1 and the area adjacent to the source area SA at the interface between the second channel area CA2 and the gate insulating layer IL1.

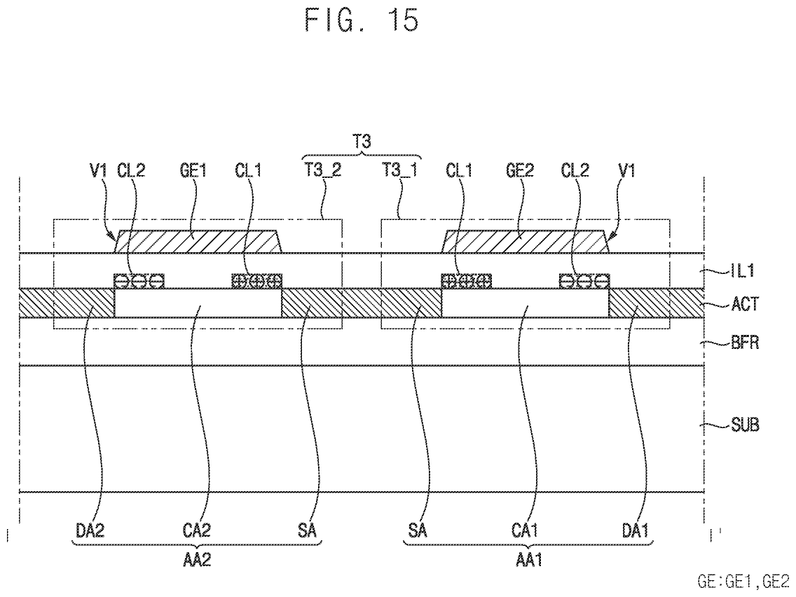

Thereafter, referring to FIG. 15, as applying the first bias voltage V1 to the gate electrode GE, the second charge layer CL2 may be formed in the area adjacent to the first drain area DA1 at the interface between the first channel area CA1 and the gate insulating layer IL1 and the area adjacent to the second drain area DA2 at the interface between the second channel area CA2 and the gate insulating layer IL1.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a transistor disposed on the substrate, wherein the transistor includes an active layer including a first active area and a second active area, wherein the first active area includes a first drain area, a source area, and a first channel area located between the first drain area and the source area, and the second active area includes the source area, a second drain area, and a second channel area located between the source area and the second drain area;
a gate insulating layer disposed on the active layer;
a first charge layer defined at an interface between the first channel area and the gate insulating layer to be adjacent to the source area and at an interface between the second channel area and the gate insulating layer to be adjacent to the source area; and
a second charge layer defined at the interface between the first channel area and the gate insulating layer to be adjacent to the first drain area and at the interface between the second channel area and the gate insulating layer to be adjacent to the second drain area, wherein the second charge layer has a charge opposite to a charge of the first charge layer.

2. The display device of claim 1, wherein the second charge layer shifts a threshold voltage of the transistor in one of a positive direction and a negative direction, and the first charge layer shifts the threshold voltage of the transistor in the other of the positive direction and the negative direction.

3. The display device of claim 1, wherein the first charge layer and the second charge layer are spaced apart from each other.

4. The display device of claim 1, wherein the transistor includes a first gate electrode overlapping the first channel area and a second gate electrode overlapping the second channel area, and
wherein the first gate electrode and the second gate electrode are electrically connected to each other.

5. The display device of claim 4, wherein the transistor includes:
a first sub-transistor defined by the first active area and the first gate electrode; and
a second sub-transistor defined by the second active area and the second gate electrode, and
wherein the first sub-transistor and the second sub-transistor are connected to each other.

6. The display device of claim 4, wherein each of the first charge layer and the second charge layer overlaps the first gate electrode and the second gate electrode when viewed in a thickness direction of the substrate.

7. The display device of claim 1, wherein each of the first drain area, the source area, and the second drain area is doped with P-type impurity ions.

8. The display device of claim 7, wherein the first charge layer has a positive charge, and the second charge layer has a negative charge.

9. The display device of claim 1, wherein each of the first drain area, the source area, and the second drain area is doped with N-type impurity ions.

10. The display device of claim 9, wherein the first charge layer has a negative charge, and the second charge layer has a positive charge.

11. The display device of claim 1, wherein the active layer includes a silicon semiconductor.

12. A method of manufacturing a display device, the method comprising:
forming an active layer including a first active area and a second active area on a substrate, wherein the first active area includes a first drain area, a source area, and a first channel area located between the first drain area and the source area, and the second active area includes the source area, a second drain area, and a second channel area located between the source area and the second drain area;
forming a gate insulating layer on the active layer;
forming a first charge layer at an interface between the first channel area and the gate insulating layer to be adjacent to the source area and at an interface between the second channel area and the gate insulating layer to be adjacent to the source area; and
forming a second charge layer having a charge opposite to a charge of the first charge layer at the interface between the first channel area and the gate insulating layer to be adjacent to the first drain area and at the interface between the second channel area and the gate insulating layer to be adjacent to the second drain area.

13. The method of claim 12, wherein the forming the first charge layer comprises selectively implanting ions to an area adjacent to the source area at the interface between the first channel area and the gate insulating layer and to an area adjacent to the source area at the interface between the second channel area and the gate insulating layer using a mask.

14. The method of claim 12, further comprising:
forming a first gate electrode overlapping the first channel area and a second gate electrode overlapping the second channel area on the gate insulating layer and;
wherein the forming the first charge layer comprises applying a bias voltage to each of the first gate electrode and the second gate electrode.

15. The method of claim 12, wherein the forming the second charge layer comprises selectively implanting ions to an area adjacent to the first drain area ay the interface between the first channel area and the gate insulating layer and to an area adjacent to the second drain area at the interface between the second channel area and the gate insulating layer using a mask.

16. The method of claim 12, further comprising:
forming a first gate electrode overlapping the first channel area and a second gate electrode overlapping the second channel area on the gate insulating layer, and
wherein the forming the second charge layer comprises applying a bias voltage to each of the first gate electrode and the second gate electrode.

17. The method of claim 12, wherein each of the first drain area, the source area, and the second drain area is doped with P-type impurity ions, the first charge layer has a positive charge, and the second charge layer has a negative charge.

18. The method of claim 12, wherein each of the first drain area, the source area, and the second drain area is doped with N-type impurity ions, the first charge layer has a negative charge, and the second charge layer has a positive charge.

19. The method of claim 12, wherein the first charge layer and the second charge layer are spaced apart from each other.

20. The method of claim 12, wherein the active layer comprises a silicon semiconductor.
